(19) United States
(12) Patent Application Publication
(10) Pub. No.: US 2016/0226015 A1
(43) Pub. Date: Aug. 4, 2016

(54) EDGE SEALING FOR BENDABLE DEVICE

(71) Applicant: Microsoft Technology Licensing, LLC, Redmond, WA (US)

(72) Inventors: Ilpo Kauhaniemi, Espoo (FI); Esa Määttä, Vantaa (FI)

(21) Appl. No.: 14/613,091

(22) Filed: Feb. 3, 2015

(51) Int. Cl. H01L 51/52; B32B 7/04; B32B 37/18; B32B 37/06; B32B 37/12; H01L 51/56; B32B 7/12

(52) U.S. Cl. CPC H01L 51/5246; H01L 51/56; B32B 7/04; B32B 7/12; B32B 37/06; B32B 37/12; B32B 37/18; H01L 2251/5338; B32B 2457/00; B32B 2307/51; B32B 2457/20

(57) ABSTRACT

A device is provided. The device comprises a first layer and a second layer, and an elastic sealing fixed to the first and second layers. The device has a planar position in which it forms a plane having a perimeter. The first and second layers are moveable in relation to each other in one or more directions which lie in the plane. The device is bendable about at least one axis which is parallel to the plane, and the elastic sealing is fixed to the first and second layers at or close to the perimeter of the plane along at least part of the perimeter. A sealing method is also provided.

### BACKGROUND

Technology of flexible multilayer electronics is becoming increasingly relevant in flexible displays and touch surfaces. Many customer electronics manufacturers are applying the flexibility technology to handheld devices, laptops, wearable devices, and other consumer electronics.

### DESCRIPTION OF THE DRAWINGS

The present description will be better understood from the following detailed description read in light of the accompanying drawings, wherein:

FIG. 1a is a schematic side view of part of a device according to an embodiment;

FIG. 1b is a schematic side view of part of a device which comprises a middle layer according to an embodiment;

FIG. 1c is a schematic side view of part of a device wherein elastic sealing is fixed to more than two layers according to an embodiment;

FIG. 1d is a schematic side view of part of a device wherein elastic sealing is fixed to outer parts of layers according to an embodiment;

FIG. 1e is a schematic side view of part of a device wherein elastic sealing is fixed to inner parts of layers according to an embodiment;

FIG. 2a is a schematic angle view of part of a device according to an embodiment;

FIG. 2b is a schematic angle view of part of a device according to an embodiment, illustrating the effects of bending;

FIG. 3a shows an example of a sealing technique wherein heat bonding is used according to an embodiment;

FIG. 3b shows an example of a sealing technique wherein elastic glue is used according to an embodiment;

FIG. 3c shows an example of sealing with a membrane between top and bottom layers which both extend outwards in relation to the remaining layers according to an embodiment;

FIG. 4 clarifies relative movement of the layers when a device is bent;

FIG. 5a is a table illustrating relative movement of layers when a device according to an embodiment is bent 45 degrees;

FIG. 5b is a similar table with a 180 degree bending angle;

FIG. 5c is a similar table with a 360 degree bending angle;

FIG. 5d is a table illustrating relative movement of layers when a thinner device according to an embodiment is bent 45 degrees;

FIG. 5e is a similar table with a 180 degree bending angle;

FIG. 5f is a similar table with a 360 degree bending angle.

Like reference numerals are used to designate like parts in the accompanying drawings.

### DETAILED DESCRIPTION

The detailed description provided below in connection with the appended drawings is intended as a description of the present examples and is not intended to represent the only forms in which the present example may be constructed or utilized. However, the same or equivalent functions and sequences may be accomplished by different examples.

The embodiments described below are not limited to implementations which solve any or all of the disadvantages of known devices and covers. Although the present examples are described and illustrated herein as being implemented with a few layers separated by a filling, the devices described are provided as an example and not a limitation. As those skilled in the art will appreciate, the presented embodiments are suitable for application in a variety of bendable devices comprising stacks of layers instead of individual layers shown, and these individual layers can be a schematic representation of various parts of a device, such as a display or a touch screen. These parts may comprise a plurality of layers.

In display devices, such as LCD (Liquid Crystal Display) devices, a sealing is used on the edges to prevent moisture and dust getting inside, and to prevent the optically transparent fluid used in the device from leaking out. It can be an adhesive or a protective material integrated e.g. with a protective sheet or a backplane.

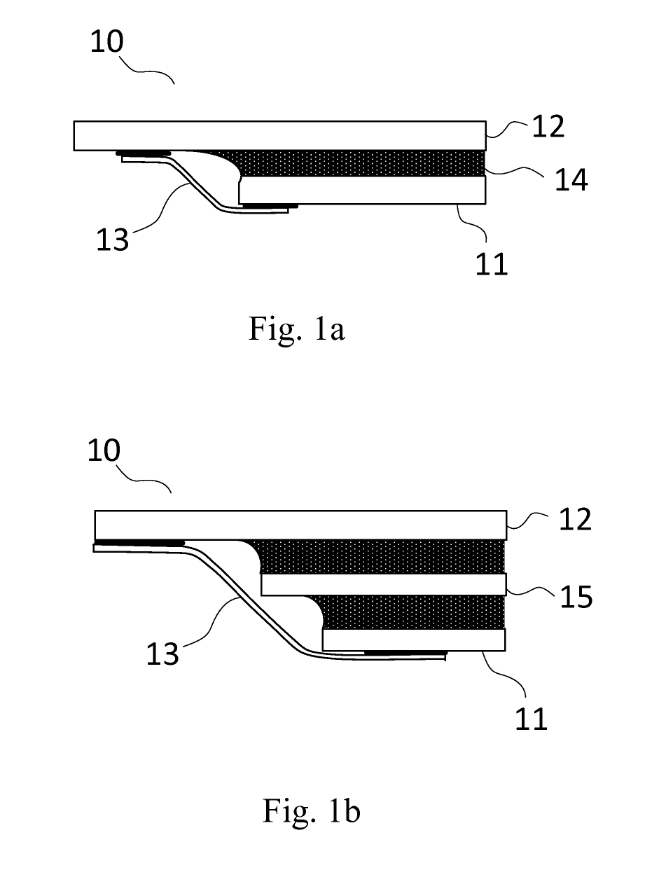

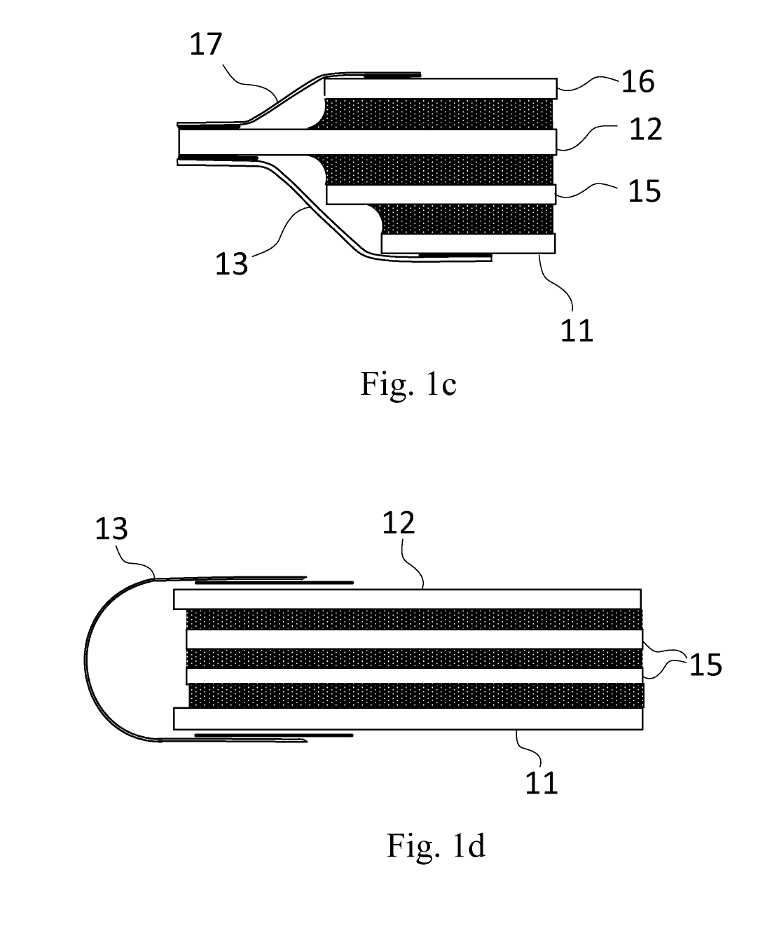

FIG. 1a shows a bendable device 10 comprising a first layer 11 and a second layer 12. This figure is a side view of one of the edges of the device 10 on the left side of the drawing, wherein the device 10 may extend further to the right side of the drawing. The term ‘bendable’ herein includes bend radius that are large with respect to the display thickness and also very small with respect to the display thickness. For example, bendable display include displays that are 3 mm thin and have may operate in a bent form in which the bend radius is 5 cm or less than 1 mm. In the latter bend radius of less than 1 mm, the display may be said to be folded, similar to a folded sheet of paper. Furthermore, ‘bendable’ refers to dynamic bending, and includes both elastic and inelastic plasticity. The device 10 comprises a display which may be implemented in any part of the device. A display can be a stacked device itself, i.e. the embodiment can apply to display devices as well as any other devices which include displays. The display may be, for example, an organic light emitting diode (OLED) display or an electronic paper display.

An elastic sealing 13 is fixed to the first and second layers 11, 12. The elastic sealing may comprise silicone rubber, latex rubber, closed cell polyurethane foam or any other flexible membrane, acrylic and/or silicone adhesive.

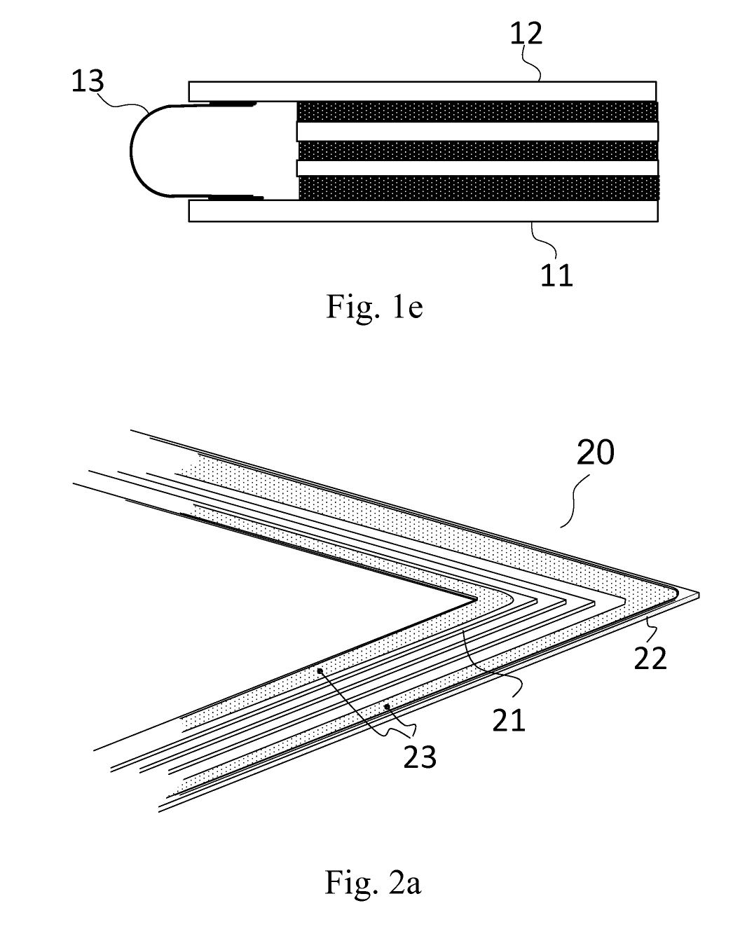

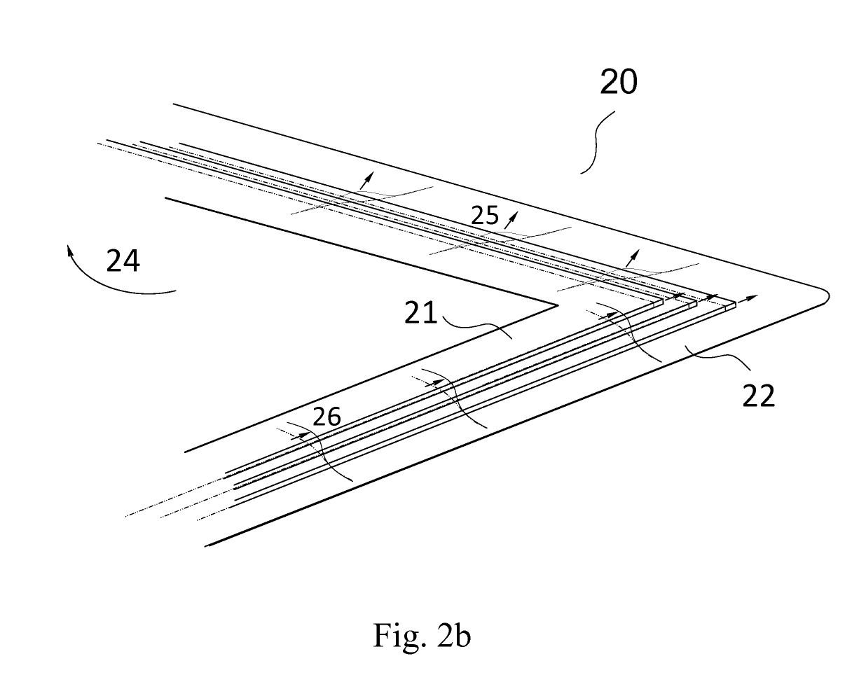

The device 10 has a planar position in which it forms a plane that has a perimeter, as illustrated in more detail below in FIG. 2. In FIGS. 1a-1e the plane schematically extends horizontally, and the perimeter of the plane follows the edge of the most outward layer, so in FIGS. 1a-1e the perimeter is along the left side of the illustration.

The first and second layers 11, 12 are moveable in relation to each other in one or more horizontal directions in the embodiment of FIG. 1a. In other words, the first and second layers 11, 12 are in a moveable connection. This connection may be a sliding connection. The space between the first layer 11 and the second layer 12 can be filled with a filling 14. The filling 14 may comprise any material suitable for the device 10, such as fluid, grease, gel and/or oil. Although the filling 14 is shown in a dark pattern on FIGS. 1a-1e, it may be fully or partially transparent and/or refractive.

The device 10 is bendable about at least one axis which is parallel to the plane. The axis may be, for example, an axis of a hinge around which the device can be bent. According to an embodiment, the axis can lie in the plane of the device itself. The elastic sealing 13 is fixed to the first and second layers 11, 12 at or close to the perimeter of the plane. According to an embodiment, the device is bendable at least 20 degrees, and according to an embodiment it is bendable more than 90 degrees. Where the device 10 is foldable or rollable, the bending may exceed 180 degrees.

The sealing 13 can prevent the filling 14 from escaping the device, as well as protect the edges of the device from outside moisture or dust. The sealing 13 may also position the first and second layers 11, 12 in relation to each other during assembly and reposition the first and second layers when the device returned to an original position the after bending.

The first and second layers 11, 12 may be bottom and top layers, depending on the positioning of the device 10. Alternatively, one of the layers 11, 12 may be a bottom layer, and the other one a middle layer with other layers on top of it.

FIG. 1b schematically illustrates a device 10 with an additional middle layer 15. As it is clear to a skilled person, the device 10 may have a plurality of middle layers, and each of the middle layers may represent an element such as a display or a touch sensor which can include a stack of layers. The middle layer 15 is positioned between the first and second layers 11, 12 and is also moveable in relation to the layers which it is connected to. In an embodiment, the elastic sealing 13 is fixed only to the first and second layers 11, 12, while providing space for movement for the middle layer 15 and the adjacent layers.

FIG. 1c shows an embodiment wherein the first layer 11 is a bottom layer, wherein the second layer 12 is a middle layer which extends outwards compared to the other layers. In this embodiment, additional layers 15 and 16 are in the stack, and the device may have two parts of the elastic sealing 13 and 17. The device shown in FIG. 1c may be viewed as a combination device wherein layer 12 serves as a bottom layer for the upper part, and layer 16 serves as a top layer for the same. The elastic sealing 13 and 17 can provide free movement of the individual layers, occurring for example when the device is bent.

In the example embodiments shown in FIGS. 1a-1c, the elastic sealing 13 (17) is fixed to the first and second layers 11, 12 (12, 16) on the same side of the device 10. The stairway-like arrangement of layers as shown in FIGS. 1a-1c, as well as fixing the elastic sealing as described above, may provide a technical effect of a smaller gap between the edges of middle layers and the elastic sealing, leaving less room for unwanted air that may, for example, get between the layers when the device is bent.

FIGS. 1d and 1e illustrate exemplary embodiments of the bendable device wherein the elastic sealing is fixed to opposite sides of the layers 11 and 12. In FIG. 1d, the sealing 13 is fixed on the outer part of the layers 11 and 12. In FIG. 1e, the sealing 13 fixed to the sides of the first and second layers 11, 12 facing each other.

The device 10 may further comprise a stack of layers between the first and second layer, for example comprising a touch sensor, a protective layer, a pressure sensitive layer, and/or polarizers. The device 10 may have a thickness between 0.15 mm and 5 mm. The layers may have a thickness of approximately 0.1 mm.

The sealing 13 may be fixed to the first and second layers 11, 12 along part of the perimeter that is parallel to the axis about which the device is bendable. In other words, the sealing 13 may be selectively applied to those parts of the perimeter which face the direction of bending. For example, if the device 10 is rectangular and the bending axis is parallel to one of the sides, the sealing may be selectively fixed to the device on those sides. This can allow combining different types of sealing on different parts of the edge of the device.

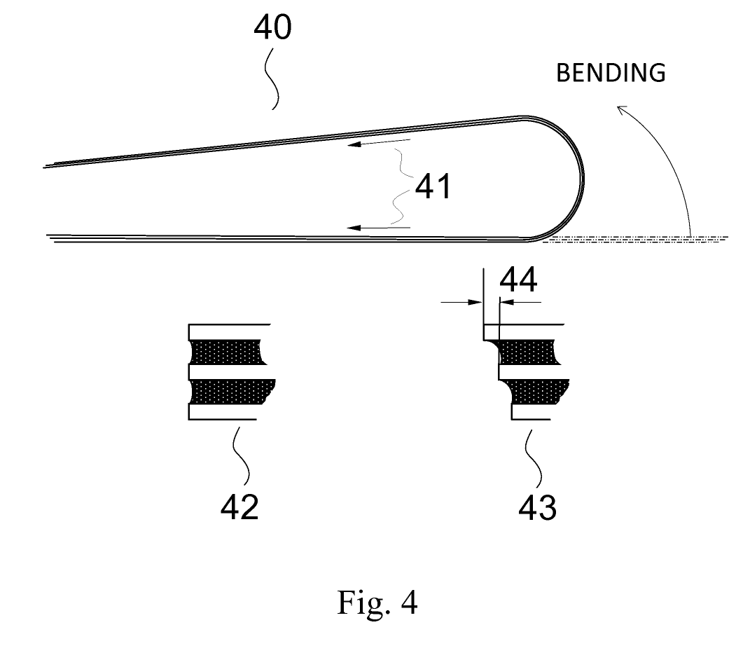

FIG. 4 shows a device 40 that is bendable over 90 degrees. This figure illustrates an example of relative movement of the layers when the device 40 is bent. The direction of movement is shown by arrows 41, wherein the layers inside the device 40 need to move, for example slide, in the direction 41 in relation to each other to avoid stress within the device and allow easy bending. The zoomed side views 42 and 43 show the edges of the device close to its perimeter when the device is planar (42) and when the device is bent (43). The relative adjacent movement of the layers is indicated by 44 and can be, for example, 0.25 mm.

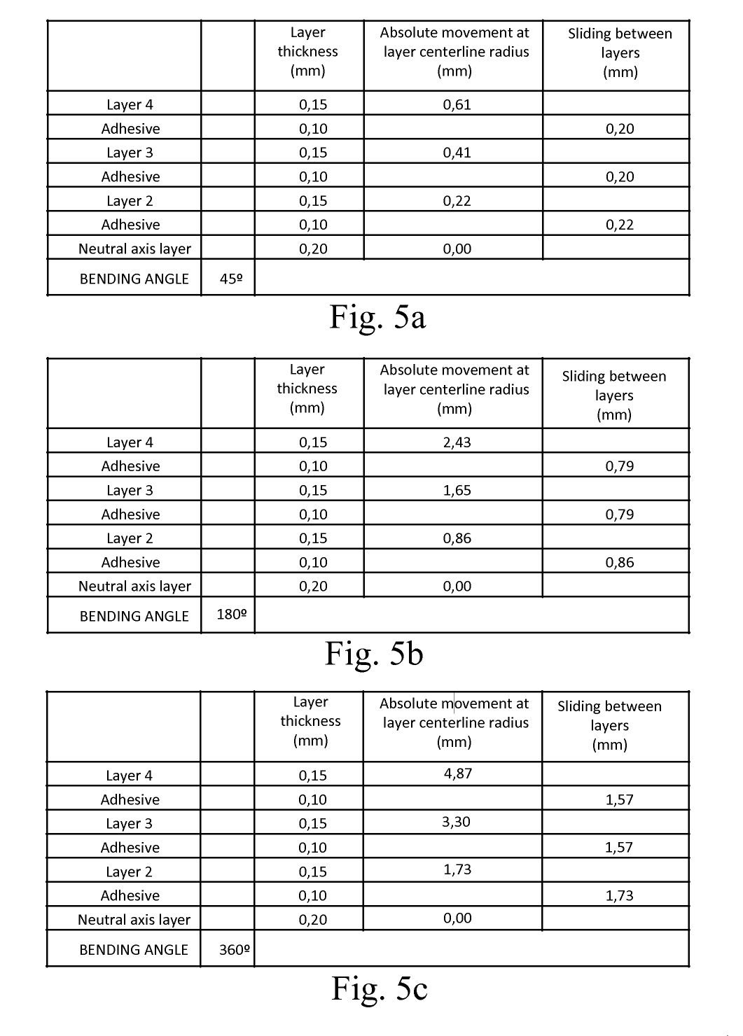

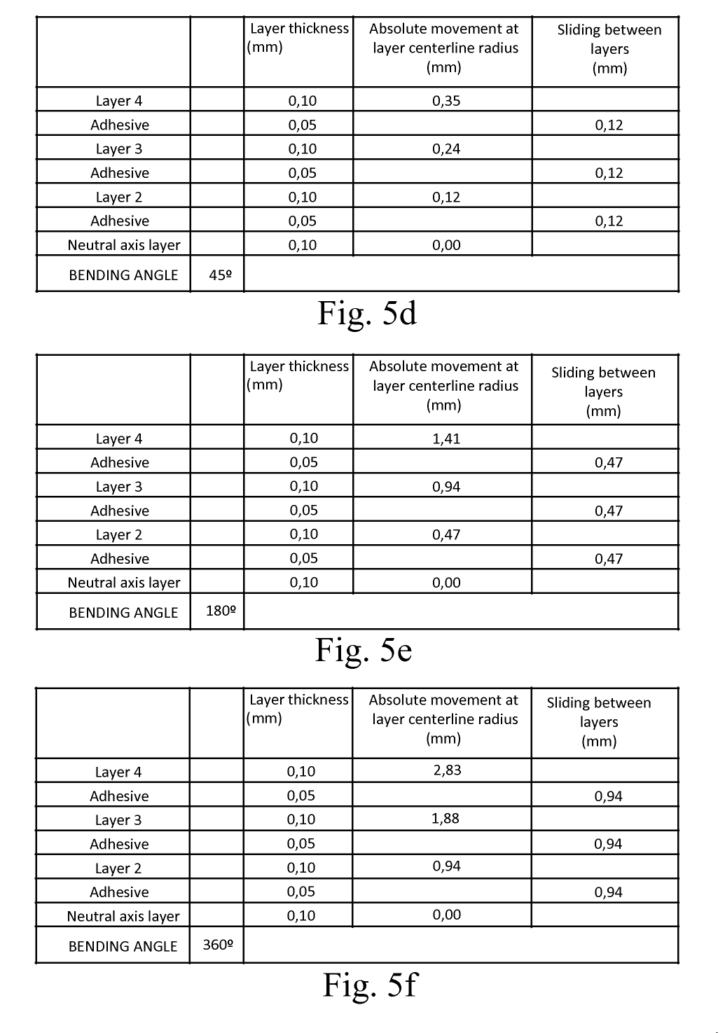

When the device 10 is bent, the layers may move in relation to each other. The movement distance can depend on thickness of each layer, number of layers and bending angle. In a rolled up device the movement distance may exceed 4 mm. FIGS. 5a-5f illustrate this movement. The figures are tables that relate to embodiments of the device with different layer thicknesses. The values presented are an approximate calculation and are in no way limiting. The device according to these embodiments comprises a neutral axis layer and three additional layers, with adhesive filling between them. In FIGS. 5a-5c, the thickness of the neutral axis layer is 0.20 millimeters, the thicknesses of layers 2-4 are 0.15 millimeters and the thicknesses of adhesives in between are 0.10 millimeters. Tables on FIGS. 5a-5c show different degrees of bending, see “Bending angle” row. The right column represents relative sliding between neighboring layers in millimeters, and the second column from the right shows absolute movement at centerline radius. The absolute movement of layer 4 also represents the distance which layer 4 travels in relation to the neutral axis layer. When the device is bent 360 degrees, e.g. rolled up, this distance may be approximately 4.87 millimeters which may require high elasticity of the seal. In the device of FIGS. 5d-5f, the layers are thinner the neutral axis and all additional layers are 0.10 millimeters thick, while the adhesive filling is 0.05 mm thick. In this case the highest presented value of absolute movement at 360 degrees is approximately 2.83 millimeters.

The device 10 comprising an elastic sealing 13 can provide free movement of the layers regardless of the degree of bending, and at the same time prevent peeling of the corners of the device 10 when it is bent. Another effect provided by the bendable device 10 comprising an elastic sealing 13 is protection of the layers and inter-layer spaces and fillings.

FIG. 2a is an angled view of a device 20 according to an example embodiment. The view shows a corner of the device 20, and in the embodiment the bottom second layer 22 extends outward further than the top first layer 21. In this figure, the device is in the planar position, forming a plane having a perimeter. For exemplary purposes two middle layers between the top and bottom layers 21, 22 are also illustrated in FIG. 2a. In an embodiment, the layers from top to bottom may form a display stack, wherein the bottom layer is a window, followed by a touch panel, a display, and the top layer forming a display support sheet

The terms ‘top’ and ‘bottom’ are used for clarity and relate to the positioning on the figures only. The elastic sealing (transparent and not fully visible on this figure) is fixed to the bottom layer 22 and the top layer 21 near the perimeter of the device 20 on the same side, i.e. on the top side. The regions of adhesion are indicated by 23 and shown as dotted areas. In an embodiment, the elastic sealing is fixed only to the first and second layers 21, 22, thereby leaving room for the middle layers to move freely while having the seal applied over them. With this kind of sealing arrangement wrinkles and/or folds at the corners can be avoided or at least minimized. Those wrinkles and folds can be difficult to avoid with seals described in FIGS. 1d and 1e.

FIG. 2b is a similar angled view of a device 20 according to an example embodiment. For exemplary purposes two middle layers are also shown in FIG. 2b. The large arrow 24 shows the direction of bending; in this case the device 20 is bent upwards parallel to one of its sides. The dotted and dashed lines illustrate the sliding of layers in relation to each other when the device is bent, showing a position before and after bending. The smaller arrows and indicators show movement of the elastic sealing on the top. When the device 20 is bent and the layers assume the position marked by dotted and dashed lines, the elastic sealing can flex and slightly bulge on the edges facing the direction of bending, as shown by 25; and stretch in the direction of layer movement on the sides, indicated by 26.

Devices according to any of the above embodiments can be used in flexible electronic devices such as wearable devices wrapping around e.g. user's wrist, foldable laptop computers where the display extends over the hinge portion and e-reader display devices that can be rolled up for storage and transportation. The devices may be embedded in or attached to a housing of a bendable or foldable apparatus.

According to an aspect, a method for sealing a bendable display device is disclosed. The method comprises first providing a bendable display device having a planar position in which the device forms a plane having a perimeter. The device comprises a first layer and a second layer moveable in relation to each other in at least one direction in the plane, for example similar to the devices described above. The method is then followed by fixing an elastic sealing to the first and second layer of the device by adhering a region of the elastic sealing to a region of the first layer, and adhering a region of the elastic sealing to a region of the second layer, at or close to the perimeter of the device along at least part of the perimeter.

In an embodiment, the method further comprises evacuating air from the environment in which the device is sealed prior to fixing the elastic sealing. In an embodiment, the device comprises at least one middle layer between the first and the second layers, and the method also comprises preventing adhesion of the at least one middle layer to the elastic sealing. The method can be carried out during assembly of the device, in which case the air can be evacuated during the deposition and subsequent sealing. Alternatively, the sealing can be carried out after the manufacture.

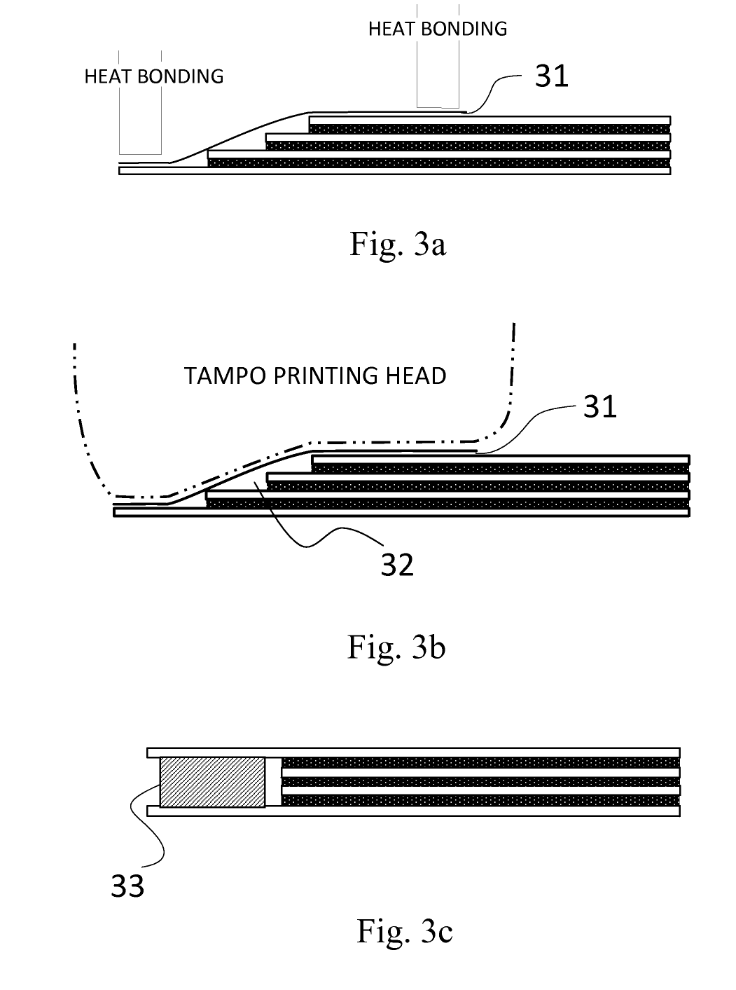

Examples of techniques for attaching a region of the elastic sealing to regions of the first and second layers are illustrated in FIGS. 3a-3b. Embodiments are not limited to these examples.

FIG. 3a shows adhesion of the elastic seal by thermal bonding. In this example, a glue sheet can be cut into shape, and the glue seal can be placed on the device and bonded with heat. The adhesion in region 31 can be selective, so the remaining parts of the elastic seal may not be adhered to any other regions of the layers.

FIG. 3b illustrates sealing by printed elastic glue. The glue seal 31 can printed on the edge using tampo printing (pad printing) or spraying. The edges of middle layers can be coated (printed) with a “non-stick material” such as oil, silicone, PTFE and others. This prevents adhesion of the seal to the middle layers. In an embodiment, the space 32 between the elastic seal and edges of the layers can be filled with oil, also preventing unwanted adhesion.

FIG. 3c shows sealing with a membrane 33 between the top and bottom layers which both extend outwards in relation to the remaining layers. This can be done by dispensing a flexible material bead on bottom layer during assembly of the device, then assembling the device so that the sealing material 33 will come into contact with the top layer, thereby sealing the edge. Materials like stiff grease or soft silicone gel may be used for this sealing. Using a membrane like the one shown in FIG. 3c can provide improved protection from the outside hazards.

According to embodiments, other techniques for fixing the elastic seal to the layers can be used. For example, the seal may be a two-sided adhesive itself, in which case a non-stick coating such as tissue paper, foam rubber sheet or printed paint can prevent adhesion in unwanted places. The two-sided adhesive may also be useful to secure the device to an outside object such as a casing or housing, using parts of the adhesive elastic sealing at the connection points.

The methods according to the embodiments above may provide the technical effect of simple and cost efficient sealing of a bendable, flexible or rollable device.

According an aspect of the invention, a bendable device with a display is disclosed. The device comprises: a first layer and a second layer, and an elastic sealing fixed to the first and second layers, wherein: the device has a planar position in which the device forms a plane having a perimeter, the first and second layers are moveable in relation to each other in one or more directions which lie in the plane, the device is bendable about at least one axis which is parallel to the plane, and the elastic sealing is fixed to the first and second layers at or close to the perimeter of the plane along at least part of the perimeter.

In an embodiment, the device further comprises at least one middle layer positioned between the first layer and the second layer, wherein the at least one middle layer is moveable in relation to the first and second layers in one or more directions which lie in the plane

In an embodiment, the elastic sealing is fixed to the first and second layers only.

In an embodiment, the second layer extends outwards in the plane in relation to the first layer, and wherein the elastic sealing is fixed to the first and second layers at or close to the perimeter of the plane on the same side of the device.

According to an embodiment, the elastic sealing is fixed to the first and second layers at or close to the perimeter of the plane on the opposite sides of the device.

In an embodiment, the first and second layers extend outwards in the plane in relation to the at least one middle layer, and wherein the elastic sealing is fixed to the sides of the first and second layers facing each other at or close to the perimeter of the plane.

In an embodiment, the device is bendable about at least one axis which lies in the plane.

In an embodiment, the elastic sealing is fixed to at least one middle layer at or close to the perimeter of the plane along at least part of the perimeter.

In an embodiment, the elastic sealing is fixed to the first and second layers along part of the perimeter that is parallel to the axis about which the device is bendable.

In an embodiment, the device is bendable more than 90 degrees.

In an embodiment, the layers are separated by a space, and the space is filled with a filling selected from the group of: fluid, grease, gel, oil and paste.

According to an aspect of the invention, a method for sealing a bendable display device is provided. The method comprises: providing a bendable display device having a planar position in which the device forms a plane having a perimeter, wherein the device comprises a first layer and a second layer moveable in relation to each other in at least one direction in the plane; fixing an elastic sealing to the first and second layer of the device by adhering a region of the elastic sealing to a region of the first layer, and adhering a region of the elastic sealing to a region of the second layer, at or close to the perimeter of the device along at least part of the perimeter.

In an embodiment, the adhering is performed by: thermal bonding, attaching with adhesive stripes, printing glue or using an adhesive elastic material in the sealing.

In an embodiment, wherein the regions of the first and second layers to which the elastic sealing is adhered are located on the same side of the device.

According to an embodiment, the method further comprises evacuating air from the environment in which the device is sealed prior to fixing the elastic sealing.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items.

Aspects of any of the examples described above may be combined with aspects of any of the other examples described to form further examples without losing the effect sought.

The term ‘comprising’ is used herein to mean including the method blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. A bendable device with a display, the device comprising:
a first layer and a second layer, and
an elastic sealing fixed to the first and second layers, wherein:
the device has a planar position in which the device forms a plane having a perimeter,
the first and second layers are moveable in relation to each other in one or more directions which lie in the plane,
the device is bendable about at least one axis which is parallel to the plane, and
the elastic sealing is fixed to the first and second layers at or close to the perimeter of the plane along at least part of the perimeter.

2. A device as claimed in claim 1, further comprising at least one middle layer positioned between the first layer and the second layer, wherein the at least one middle layer is moveable in relation to the first and second layers in one or more directions which lie in the plane.

3. A device as claimed in claim 2, wherein the elastic sealing is fixed to the first and second layers only.

4. A device as claimed in claim 1, wherein the second layer extends outwards in the plane in relation to the first layer, and wherein the elastic sealing is fixed to the first and second layers at or close to the perimeter of the plane on the same side of the device.

5. A device as claimed in claim 1, wherein the elastic sealing is fixed to the first and second layers at or close to the perimeter of the plane on the opposite sides of the device.

6. A device as claimed in claim 2, wherein the first and second layers extend outwards in the plane in relation to the at least one middle layer, and wherein the elastic sealing is fixed to the sides of the first and second layers facing each other at or close to the perimeter of the plane.

7. A device as claimed in claim 1, wherein the device is bendable about at least one axis which lies in the plane.

8. A device as claimed in claim 2, wherein the elastic sealing is fixed to at least one middle layer at or close to the perimeter of the plane along at least part of the perimeter.

9. A device as claimed in claim 1, wherein the elastic sealing is fixed to the first and second layers along part of the perimeter that is parallel to the axis about which the device is bendable.

10. A device as claimed in claim 1, wherein the device is bendable at least 20 degrees.

11. A device as claimed in claim 10, wherein the device is bendable more than 90 degrees.

12. A device as claimed in claim 1, wherein the first and second layers are in a sliding connection.

13. A device as claimed in claim 1, wherein the layers are separated by a space, and the space is filled with a filling selected from the group of: fluid, grease, gel, oil and paste.

14. A method for sealing a bendable display device, the method comprising:
providing a bendable display device having a planar position in which the device forms a plane having a perimeter, wherein the device comprises a first layer and a second layer moveable in relation to each other in at least one direction in the plane;
fixing an elastic sealing to the first and second layer of the device by adhering a region of the elastic sealing to a region of the first layer, and adhering a region of the elastic sealing to a region of the second layer, at or close to the perimeter of the device along at least part of the perimeter.

15. A method as claimed in claim 14, wherein the adhering is performed by: thermal bonding, attaching with adhesive stripes, printing glue or using an adhesive elastic material in the sealing.

16. A method as claimed in claim 14, wherein the regions of the first and second layers to which the elastic sealing is adhered are located on the same side of the device.

17. A method as claimed in claim 14, wherein the regions of the first and second layers to which the elastic sealing is adhered are located on the opposite sides of the device.

18. A method as claimed in claim 14, comprising evacuating air from the environment in which the device is sealed prior to fixing the elastic sealing.

19. A method as claimed in claim 14, wherein the device comprises one or more middle layers between the first and the second layers, and the method comprises preventing adhesion of the elastic sealing to the one or more middle layers.

20. A bendable display device, comprising:
a top layer and a bottom layer,
at least one stack element positioned between the top and the bottom layers, and
an elastic sealing fixed to the top and bottom layers only, wherein:
the device has a planar position in which the device forms a plane having a perimeter,
the top and bottom layers and the at least one stack are in a sliding connection with each other,
the device is bendable about at least one axis which is parallel to the plane,
the top and bottom layers and the at least one stack are adapted to slide in relation to each other when the device is bent,
the elastic sealing is fixed to the first and second layers at or close to the perimeter of the plane along at least part of the perimeter on one side of the device, and
at least one stack element comprises a display element.
